(19) United States
(12) Patent Application Publication
(10) Pub. No.: US 2007/0228507 A1
(43) Pub. Date: Oct. 4, 2007

(54) Electric double layer capacitor

(75) Inventors: Koji Endo, Hirakata-City (JP); Yasuo Nakahara, Hirakata-City (JP); Kikuko Kato, Hirakata-City (JP); Hiroshi Nonoue, Hirakata-City (JP)

Correspondence Address: MASUVALLEY & PARTNERS, 8765 AERO DRIVE, SUITE 312, SAN DIEGO, CA, 92123, US

(73) Assignee: Sanyo Electric Co., Ltd., Moriguchi-City (JP)

(21) Appl. No.: 11/700,460

(22) Filed: Jan. 31, 2007

(30) Foreign Application Priority Data
Mar. 31, 2006 (JP) JP2006-100876

(51) Int. Cl. H01L 29/00

(52) U.S. Cl. 257/499; 257/E29.343

(57) ABSTRACT

The current invention provides for an electric double layer capacitor which can be manufactured with low manufacturing cost, and an increase of internal resistance due to the damage of a cathode current collector by reflow is inhibited. For this reason, in the current invention, the electric double layer capacitor comprising a cathode 1a, anode 1b, a separator 1c to separate said cathode 1a and anode 1b, electrolytic solution 7 and a container 10 to house said cathode 1a, anode 1b, separator 1c and electrolytic solution 7, wherein said cathode 1a is electrically connected to cathode current collector 2, and said cathode current collector 2 is comprised of alloy of a metal element showing an oxide passivation phenomenon and aluminum.

### TECHNICAL FIELD

The present invention relates to an electric double layer capacitor.

### BACKGROUND OF INVENTION

An electric double layer capacitor has been proposed in recent years, the electric double layer capacitor is configured to provide terminals to an outer container made of ceramics or other materials, to house a pair of electrodes, a separator between the pair of electrodes, and electrolytic solution inside of the outer container, and to seal an opening portion by attaching sealing plate on the opening portion of the outer container.

When employing such an electric double layer capacitor as back-up power supply or supplemental power supply for cellular phone and home electric appliances, the electric double layer capacitor is reflow soldered onto a printed wiring board. Therefore, it is necessary to select components that do not deteriorate even when they are exposed to temperatures of 200-300 degree/C. for a few seconds during soldering.

In the electric double layer capacitor, as indicated in the Japanese published unexamined patent application no. 2004-227959 and 2005-210064, gold (Au) or aluminum (Al) has been used as a current collector material when a current collector is provided to an inner bottom face of the concave container side of the outer container.

When Au is used as a cathode current collector, there are issues of expense but also a short cycle life due to an increase of the internal resistance of the capacitor because Au dissolves in the electrolytic solution when a high voltage exceeding 3V is applied between a cathode and an anode.

When Al is used as a cathode current collector, dissolution due to application of a high voltage is inhibited, however, there is an issue of a sudden increase of internal resistance due to reflow. The cause of the increase of internal resistance due to reflow is thought to be due to an insulation property of aluminum halide, such as aluminum fluoride or aluminum chloride, formed on the current collector surface at the position where it is electrically connected with a cathode, due to a reaction of aluminum with a halogen ion, such as fluoride ion or chloride ion that exists in the electrolytic solution impregnated into a cathode. Such increase of internal resistance decreases voltage of the capacitor by IR drop and results in a decrease of discharge capacity.

The objective of the current invention is to decrease the manufacturing cost of an electric double layer capacitor, and to suppress an internal resistance increase due to reflow or high voltage applications to the cathode current collector in an electric double layer capacitor.

### BRIEF SUMMARY OF THE INVENTION

In order to resolve such issues described above, the electric double layer capacitor of the current invention is an electric double layer capacitor comprising a cathode, an anode, a separator to separate said cathode and anode, electrolytic solution, and a container to house said cathode, anode, separator, and electrolytic solution, wherein said cathode is electrically connected to a cathode current connector, and said cathode current collector is comprised of an alloy of a metal element showing an oxide passivation phenomenon and aluminum.

At this time, the passivation phenomenon is a phenomenon where the surface of a metal is covered by an insoluble ultra thin film, such as an oxide, thereby inhibiting corrosion.

At this time, chromium (Cr), nickel (Ni), iron (Fe), Cobalt (Co), molybdenum (Mo), Titanium (Ti), Tantalum (Ta), Niobium (Nb), Zirconium (Zr), and tungsten (W) may be listed as the metal element described above.

In addition, the above-mentioned metal element may be chromium.

Chromium content in the above-mentioned alloy may be no less than 10 atomic % (“at %”) and no more than 95 atomic % (“at %”).

Alternatively, chromium content in the above-mentioned alloy may also be no less than 20 atomic % and no more than 80 atomic %.

Also, the metal element may be nickel. And in this case, the nickel content in an alloy may be no less than 5 atomic % and no more than 50 atomic %.

The metal element may be molybdenum or tungsten.

Alternatively, the cathode current collector may be a film having a thickness no less than 0.3 μm and no more than 50 μm.

Further, the electric double layer capacitor of the second embodiment is an electric double layer capacitor comprising a cathode, an anode, a separator to separate said cathode and anode, electrolytic solution, and a container to store said cathode, anode, separator, and electrolytic solution, wherein said cathode is electrically connected to a cathode current collector, and said cathode current collector is comprised of an alloy of chromium and aluminum.

In addition, the chromium content in the above-mentioned alloy may also be no less than 10 atomic % and no more than 95 atomic %.

Alternatively, the cathode current collector may be a film having a thickness no less than 0.31 μm and no more than 50 μm.

Still further, the electric double layer capacitor of a third embodiment is an electric double layer capacitor comprising a cathode, an anode, a separator to separate said cathode and anode, electrolytic solution, and a container to store said cathode, anode, separator, and electrolytic solution, wherein said cathode is electrically connected to a cathode current collector, said cathode current collector is comprised of an alloy of chromium and aluminum, and chromium content of said alloy is approximately 50 atomic %.

According to the electric double layer capacitor of the current invention, it is possible to inhibit increases of internal resistance both dissolution of a current collector material when a high voltage is applied, and formation of aluminum halide at soldering reflow. As for this cause, it is thought that by using a cathode current collector made of an alloy of a metal element which shows an oxide passivation phenomenon and aluminum, the oxide film forming on its surface is further densified and thereby inhibits halogen ions contacting the cathode current collector, so that formation of aluminum halide, which is an insulator, is therefore inhibited. Also, since the oxide film is very thin, a formation of oxide film barely increases the internal resistance.

### BRIEF DESCRIPTION OF THE DRAWINGS

FIG. 1 is a cross section diagram of an electric double layer capacitor according to one embodiment of the current invention.

FIG. 2 illustrates a relationship between Cr contents in a cathode current collector comprised of an Al—Cr alloy and internal resistance after each process.

FIG. 3 illustrates changes in Ni contents in a cathode current collector comprised of an Al—Ni alloy and internal resistance after each process.

### DETAILED DESCRIPTION OF THE INVENTION

An electric double layer capacitor of the current invention will hereinafter be described in reference to the drawing. In addition, the electric double layer capacitor of the current invention is not limited to the embodiments indicated below and changes may be made without departing from the scope of the invention.

### Embodiment 1

A configuration of the electric double layer capacitor of a first embodiment is explained using FIG. 1. FIG. 1 is a schematic diagram showing a cross section of an electric double layer capacitor 100. In the electric double layer capacitor 100, as shown in FIG. 1, an electrode pile 1 provided with a separator 1c between cathode 1a and anode 1b is housed in a containing portion 11 of an outer container 10.

A coating layer 4 is provided to the surface of bottom portion 16 of containing portion 11 in the outer container 10, and a cathode current collector 2 is arranged on the coating layer 4. Also, the cathode current collector 2 is provided such that it is electrically connected on the surface of cathode 1a by attaching with a conductive paste. Further, a cathode connecting terminal 5a is provided so that it contacts with the cathode current collector 2. The cathode connecting terminal 5a extends towards side wall 17 of the outer container 10 and contacts with the bottom portion of the containing portion 11, and further extends to the bottom face 18 of the outer container 10 through side wall 17.

That is, as shown in FIG. 1, the cathode 1a and the cathode connecting terminal 5a are electrically connected through the cathode current collector 2, and configured in a way that a portion of cathode connecting terminal 5a does not touch the electrolytic solution 7 by coating a portion of the cathode connecting terminal 5a with the coating layer.

Also, an anode connecting terminal 5b which extends from an edge portion 19 of opening portion 6 on the upper face of containing portion 11 to the bottom face 18 of outer container 10, is provided to outer container 10.

Further, a sealing plate 20 having an anode current collector 3 formed on a face of the side that contacts to the anode 1b, is arranged in a way in which it covers an opening portion 6 on the upper side of the containing portion 11 of outer container 10. A this time, the sealing plate 20 is pressed against the anode 1b so that the anode current collector 3 contacts the anode 1b, and in this condition, the sealing plate 20 is attached to an edge portion 19 of outer container 10 by welding, thereby sealing the opening portion 6 of outer container 10.

That is, as shown in FIG. 1, the anode 1b and the anode connecting terminal 5b are electrically connected through the anode current collector 3, and configured in a way that a portion of anode connecting terminal 5b does not touch the electrolytic solution 7.

Further, electrolytic solution 7 is filled in the containing portion 11 to sufficiently impregnate the cathode 1a and the anode 1b.

For outer container 10, for example, insulating materials having a rigidity, such as ceramics, and heat resistant plastics may be used.

For cathode 1a and anode 1b, substances which can be impregnated by an electrolytic solution may be used. For example, mixture of a carbon material, such as activated carbon, and a binder, such as polytetrafluoroethylene, which is pressure formed into a predetermined size or an activated carbon fiber cloth, may be used.

For separator 1c, for example, glass fiber or cellulose fiber may be used.

For coating layer 4, for example, materials not corrosive to electrolyte, such as, an oxide like alumina and silica, alternatively nitride, carbide, and other materials may be used.

For anode current collector 3, for example, gold or nickel may be used.

For sealing plate 20, for example, nickel or aluminum, stainless, aluminum alloy, and Fe—Ni—Co alloy may be used.

For electrolytic solution 7, for example, an organic electrolytic solution is used. At this time, the solvent to be used for the electrolytic solution may be anything that can dissolve electrolyte, thus publicly known solvents which are commonly used, can be employed. For example, ethylene carbonate, propylene carbonate, butylene carbonate, y-butyrolactone, y-valerolactone, sulfolan, ethylene glycol, polyethylene glycol, vinylene carbonate, chloroethlene carbonate, dimethyl carbonate, diethyl carbonate, methylethyl carbonate, dipropyl carbonate, dibutyl carbonate, dimethoxymethane, dimethoxyethane, methoxyethoxyethane, diethoxyethane, tetrahydrofuran, 2-methyl-tetrahydrofuran, dimethylhormamide, dimethylsulfoxide, acetonitrile, methyl formate, dioxolan, 4-methyl-1,3-dioxolan, may be used. Alkali metal salt, ammonium salt and so on may be used as an electrolyte in the above electrolytic solution. For example, Li⁺, (CH₃)₄N⁺, (CH₃)₃C₂H₅N⁺, (CH₃)₂(C₂H₅)₂N⁺, CH₃(C₂H₅)₃N⁺, (C₂H₅)₄N⁺, (C₃H₇)₄N⁺, (C₄H₉)₄N⁺, and so on may be used as a cation of the electrolyte salt, and ClO₄⁻, BF₄⁻, PF₆⁻, CF₃SO₃⁻, (CF₃SO₂)₂N⁻, C₄F₉SO₃⁻, B₁₀Cl₁₀²⁻, B₁₂Cl₁₂²⁻ and so on may be used as anion of the electrolyte salt. The current invention shows an effect specially when using electrolytic solution containing halogen ion.

For cathode connecting terminal 5a and anode connecting terminal 5b, for example, high melting point metal, such as tungsten (W), molybdenum (Mo) and so on may be used. For the interface between the cathode connecting terminal 5a and the cathode current collector 2, for example, Ni or Au may be formed. Also, for both of these connecting terminals, double layer plating structure comprised of Ni plating layer and Au plating layer may be formed.

Although, in the electric double layer capacitor of this embodiment, an electrode pile 1 provided with the separator 1c between the cathode 1a and the anode 1b, is housed inside of the containing portion 11 of the outer container 10, different configurations of an electrode pile can be used. The cathode 1a and the anode 1b may be fixed with a spacer not to contact each other, for example fixing the cathode 1a and anode 1b apart from each other by using the spacer to retain a surrounding part of the cathode 1a and anode 1b, and housed inside of the containing portion 11 of outer container 10.

### Embodiment 1

A manufacturing method for the electric double layer capacitor according to one embodiment of the current invention is hereinafter explained.

First, the cathode current collector 2 comprised of an alloy having Al and Cr is formed on a predetermined position on the bottom face 16 of the containing portion 11 in the outer container 10 by the spattering method. The outer container 10 is placed within the film formation room such that the bottom face 16 of the containing portion 11 in the outer container 10 and a spattering target are facing each other, and placing a metal mask, which is to be formed in a film on a predetermined position on the bottom face of the outer container 10, between the outer container 10 and the spattering target, thereby the cathode current collector 2 is formed. In this embodiment, the cathode current collector 2 comprised of Al—Cr alloy in thickness of 1 μm is formed in a way that Cr content in the alloy is approximately 50 atomic % by placing a Cr chip with purity of 99.9% onto an Al target with a purity of 99.999% and forming in a film by the spattering method.

At this time, as for the outer container 10, a container comprised of alumina with a linear expansion coefficient of 7×10⁻⁶ K⁻¹, consisting of a frame in a square form 5.0 mm on a side and 1.3 mm in height, and a containing portion 11 in a square form 3.6 mm on a side and 1.1 mm in depth formed on the upper face of the frame, is used. As shown in FIG. 1, the cathode connecting terminal 5a comprised of tungsten which is penetrating the side wall 17 and drawn into the bottom portion 16 of the containing portion 11 described above in this outer container 10 from outside of the container, is formed. This cathode connecting terminal 5a is exposed only in the center portion and the rest is covered by a coating layer 4 comprised of alumina. This coating layer prevents the cathode connecting terminal 5a from contacting the electrolytic solution 7. The cathode current collector 2 is formed so that it covers this exposed cathode connecting terminal 5a. The cathode connecting terminal 5a protrudes from the side wall 17 of outer container 10 and extends to its bottom face 18. Also, an anode connecting terminal 5b, which extends from the edge portion 19 of outer container 10 described above, to the bottom face 18, is provided.

Also, in this embodiment, the electrode has been fabricated such that mixing 100 weight parts of activated carbon powder with a specific surface area of approximately 1500 m²/g, 5 weight parts of acetylene black, and 5 weight parts of polytetrafluoroethylene (PTFE), then forming such mixture into a square 2.0 mm on a side with a thickness of 0.5 mm.

Further, the electrolytic solution 7 is prepared by using propylene carbonate as a solvent and dissolving (C₂H₅)₄NBF₄ as a solute in a way that concentration is 1 mol per liter.

For sealing plate 20, a Fe—Ni—Co alloy with a linear expansion coefficient of 5×10⁻⁶ K⁻¹ and a thickness of approximately 0.1 mm. is employed. The face of the sealing plate contacting the anode is applied with a double plating layer structure of a Ni plating layer and an Au plating layer

In fabricating the electrical double layer capacitor 100, as shown in FIG. 1, the electrode pile 1 which includes the separator 1c made of grass fiber, between the cathode 1a and the anode 1b fabricated as described above, is housed in the containing portion 11 of outer container 10 described above, and then the cathode 1a is attached to the cathode current collector 2 provided to the bottom face 16 of the containing portion 11, with a conductive paste, thereafter, the containing portion of this outer container 10 is filled with electrolytic solution 7 to sufficiently impregnate the cathode 1a with electrolytic solution. Next, the electric double layer capacitor 100 is fabricated by welding the above-mentioned sealing plate onto the edge portion 19 of the outer container 10.

### Embodiment 2

In this embodiment, the electric double layer capacitor 100 has been fabricated as the first Embodiment except for forming the cathode current collector 1a comprising Al—Ni alloy in a thickness of 1 μm in a way that Ni content in the alloy is approximately 50 atomic % by placing a Ni chip in a purity of 99.99% onto an Al target in a purity of 99.999% then forming a film by the spattering method.

### Embodiment 3

In this embodiment, the electric double layer capacitor 100 has been fabricated as described in the first Embodiment except for forming the cathode current collector 2 comprising an Al—Mo alloy in a thickness of 1 μm in a way that the Mo content in the alloy is approximately 12 atomic % by placing the Mo chip in a purity of 99.9% onto an Al target in a purity of 99.999%, then forming a film by the spattering method.

### Embodiment 4

In this embodiment, the electric double layer capacitor 100 has been fabricated as described in the first Embodiment except for forming the cathode current collector 1a comprising an Al-W alloy in a thickness of 1 μm in a way that W content in the alloy is approximately 6 atomic % by placing a W chip in a purity of 99.9% onto an Al target in a purity of 99.999%, then forming a film by the spattering method.

### COMPARATIVE EXAMPLE 1-4

For Comparative examples 1, 2, 3, and 4, the electric double layer capacitor 100 has been fabricated as described in the first Embodiment (Embodiment 1) except for forming the cathode current collector 2 comprising Al, Cr, Ni, Au respectively in a thickness of 1 μm by forming a film by the spattering method using targets comprising Al, Cr, Ni, and Au respectively.

### (Measurement)

Next, for each electric double layer capacitor of Embodiments 1-4 and Comparative examples 1-4 fabricated as described above, the internal resistance (ohm) of the capacitor as fabricated is measured at ambient temperature applying an alternating current (0.1 mA) at a frequency of 1 kHz.

Next, carried out a soldering reflow which is to repeat three thermal treatments of heating each electric double layer capacitor at 170 degree/C. for 5 minutes and 260 degree/C. for 1 minute, and the internal resistance of each electric double layer capacitor after the reflow is measured in the same way as described above.

Thereafter, 10 cycles of charge and discharge is conducted to each electric double layer capacitor, wherein one cycle comprised of charging at a constant voltage of 3.2V in an atmosphere of 60 degree/C. for 1 hour and then discharging down to 2.0V at a constant current of 0.2 mA. Subsequently, the internal resistance of each electric double layer capacitor is measured in the same way as described above.

Table 1 shows the measurement results.

TABLE 1

| | | Internal resistance | Internal resistance | Internal resistance |
|---|---|---|---|---|
| | Current collector | after assembly | after reflow | after 10 cycles |
| | material | (Ohm) | (Ohm) | (Ohm) |
| Embodiment 1 | Al—Cr (50 at %) | 32 | 36 | 113 |
| Embodiment 2 | Al—Ni (50 at %) | 31 | 33 | 190 |
| Embodiment 3 | Al—Mo (12 at %) | 32 | 35 | 95 |
| Embodiment 4 | Al—W (6 at %) | 30 | 33 | 101 |
| Comparative | Al | 30 | 1057 | 1213 |
| example 1 | | | | |
| Comparative | Cr | 29 | 32 | 877 |
| example2 | | | | |
| Comparative | Ni | 29 | 30 | 480 |
| example3 | | | | |
| Comparative | Au | 29 | 29 | 93 |
| example4 | | | | |

Also, the internal resistance of each electric double layer capacitor is measured for Embodiments 1, 3, 4, and Comparative example 4 by the method described above, after conducting a total of 100 charge-discharge cycles.

Table 2 shows the measurement results.

TABLE 2

| | | Internal resistance | Internal resistance |
|---|---|---|---|
| | Current collector | after 10 cycles | after 100 cycles |
| | material | (Ohm) | (Ohm) |
| Embodiment 1 | Al—Cr (50 at %) | 113 | 168 |
| Embodiment 3 | Al—Mo | 95 | 155 |
| | (12 at %) | | |
| Embodiment 4 | Al—W (6 at %) | 101 | 161 |
| Comparative | Au | 93 | 3000 |
| Example 4 | | | |

As it is apparent from table 1, the internal resistance significantly increased after reflow for Comparative example 1. This is thought to be due to formation of aluminum fluoride, which is insulating on the surface of the aluminum cathode current collector.

Also, the internal resistance significantly increased after 10 charge-discharge cycles for Comparative examples 2 and 3. This is thought to be due to a dissolution of current collector material into the electrolytic solution under the application of voltage exceeds 3V.

On the contrary, increases of internal resistance were inhibited even after 10 charge-discharge cycles for Embodiments 1, 2, 3, and 4 compared to Comparative examples 1, 2, and 3.

Also, as it is apparent from table 2, for comparative example 4, the internal resistance after 10 charge-discharge cycles is comparable to those of Embodiment 1 and 3, however, the internal resistance significantly increased after 100 charge-discharge cycles. This is thought to be due to dissolution of portion of Au, which is the cathode current collector material, into the electrolytic solution.

On the contrary, increases of internal resistance are small for Embodiments 1, 3, and 4 even after 100 charge-discharge cycles, thus it become apparent that the electric double layer capacitor using Al—Cr (50 atomic %), Al—Mo (12 atomic %), and Al—W (6 atomic %) as the cathode current collector material is specially superior in long term characteristics.

### Embodiment 5

Next, a difference in internal resistance by Cr contents is examined using an Al—Cr alloy as a cathode current collector material.

In this embodiment, Cr contents in the alloy were changed by changing the number of Cr chips to be arranged on an Al target when forming a cathode current collector. Except for this point, the electric double layer capacitor was fabricated in the same method as the first embodiment.

As described above, the internal resistance after reflow, the internal resistance after 10 charge-discharge cycles, and the internal resistance after 100 charge-discharge cycles was measured for each electric double layer capacitor having a different Cr content fabricated as above.

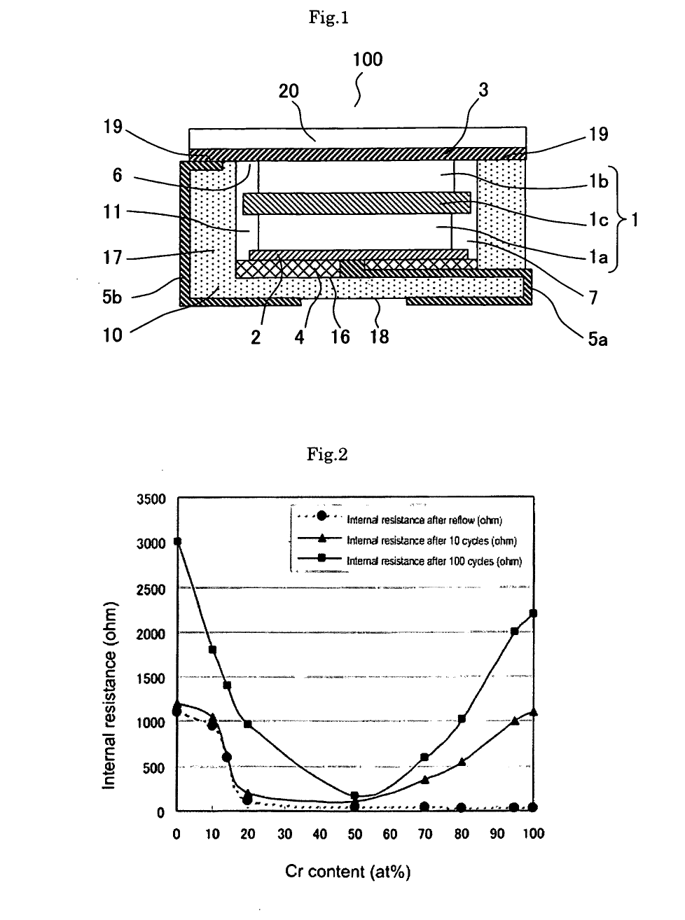

FIG. 2 shows the relationship between Cr contents in an Al—Cr alloy, internal resistance after 10 charge-discharge cycles, and internal resistance after 100 charge-discharge cycles.

When using an electric double layer capacitor as a back-up power supply, the internal resistance is desirable to be 1000 ohm or below. From FIG. 2, it is apparent that the internal resistances after 10 charge-discharge cycles are 1000 ohm or below when the Cr contents are in a range of 10-95 atomic %. Also, it is apparent that the internal resistances after 100 charge-discharge cycles are in 1000 ohm or below when the Cr contents are in a range of 20-80 atomic %. Therefore, Cr content in an Al—Cr alloy is desirable to be 10-95 atomic %, and further desirable to be 20-80 atomic %.

### Embodiment 6

Next, a difference in internal resistance by Ni content is examined using an Al—Ni alloy as a cathode current collector material.

In this embodiment, Ni contents in the alloy were changed by changing the number of Ni chips to be arranged on an Al target when forming a cathode current collector. Except for this point, the electric double layer capacitor was fabricated in the same method as embodiment 2.

As described above, the internal resistance after reflow, and the internal resistance after 20 charge-discharge cycles was measured for each electric double layer capacitor provided with a cathode current collector having a different Ni content fabricated as above.

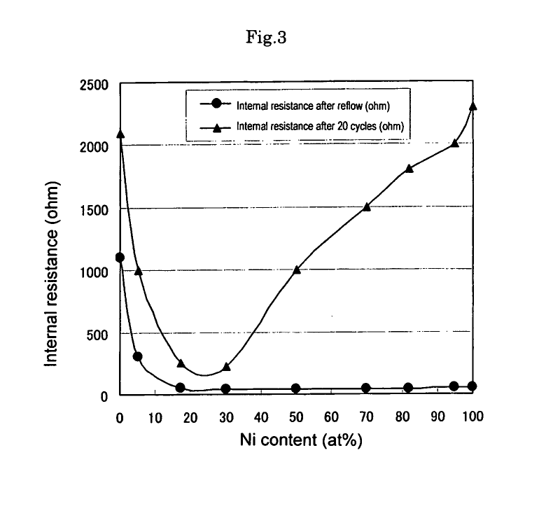

FIG. 3 illustrates a relationship between Ni content in an Al—Ni alloy, internal resistance after reflow, and internal resistance after 20 charge-discharge cycles.

From FIG. 3, it is apparent that the internal resistance after 20 charge-discharge cycles are in 1000 ohm or below when the Ni content is in a range of 5-50 atomic %. Therefore, Ni content in an Al—Ni alloy is desirable to be 5-50 atomic %.

### Embodiment 7

Next, a difference in internal resistance by thickness of a cathode current collector is examined using an Al—Cr alloy with a Cr content of 50 atomic % as a cathode current collector material.

In this embodiment, thickness of the cathode current collector was changed by changing time and speed for forming a cathode current collector. Except for this point, the electric double layer capacitor was fabricated in the same method as embodiment 1.

As described above, the internal resistance after reflow, and the internal resistance after 10 charge-discharge cycles was measured for each electric double layer capacitor having a cathode current collector with different thicknesses fabricated as above.

Table 3 shows measurement results of internal resistance after 10 charge-discharge cycles.

TABLE 3

| Film thickness(μm) | Internal resistance after 10 cycles (ohm) |
|---|---|
| 0.2 | 1800 |
| 0.3 | 1000 |
| 1.0 | 40 |

Table 4 shows measurement results of internal resistance after reflow.

TABLE 4

| Film thickness (μm) | Internal Resistance after reflow (ohm) |
|---|---|
| 10 | 42 |
| 50 | 41 |
| 100 | >3000 |

As it is apparent from table 3, the internal resistance is significantly increased exceeding 1000 ohm when the thickness of the cathode current collector is 0.2 μm. This is considered to result from the corrosion of the cathode connecting terminal 15a comprised of tungsten. The thickness of the cathode current collector is so thin that there are pin holes on the cathode current collector and the electrolytic solution penetrated into the pin holes.

Also, as it is apparent from table 4, internal resistance after reflow is significantly increased, exceeding 1000 ohm when the thickness of the cathode current collector is 100 μm. This is thought to result from separation of the cathode current collector from the cathode connecting terminal 15a due to increase of stress in the film used as the cathode current collector.

Therefore, it is apparent that the thickness of the cathode current collector is preferable to be no less than 0.3 μm and no more than 50 μm.

In addition, it was determined that the reference value of internal resistance is desirable to be 1000 ohm or below, however, there is a possibility for a decrease in power consumption or a decrease in minimum operating voltage due to continued technical development of portable devices, thus there may be a possibility that an electric double layer capacitor with internal resistance exceeding 1000 ohm can be used. Therefore, the electric double layer capacitor of the current invention is not limited to the internal resistance of 1000 ohm or less.

What is claimed is:

1. An electric double layer capacitor comprising a cathode, an anode, a separator to separate said cathode and anode, an electrolytic solution, and a container to house said cathode, anode, separator, and electrolytic solution,
wherein said cathode is electrically connected to a cathode current collector, and said cathode current collector is comprised of an alloy of a metal element showing an oxide passivation phenomenon and aluminum.

2. The electric double layer capacitor according to claim 1, wherein said metal element is chromium.

3. The electric double layer capacitor according to claim 2, wherein said chromium content is no less than 10 atomic % and no more than 95 atomic %.

4. The electric double layer capacitor according to claim 2, wherein said chromium content is no less than 20 atomic % and no more than 80 atomic %.

5. The electric double layer capacitor according to claim 1, wherein said metal element is nickel.

6. The electric double layer capacitor according to claim 5, wherein said nickel content is no less than 5 atomic % and no more than 50 atomic %.

7. The electric double layer capacitor according to claim 1, wherein said metal element is molybdenum.

8. The electric double layer capacitor according to claim 1, wherein said metal element is tungsten.

9. The electric double layer capacitor according to claim 1, wherein said cathode current collector is a film in a thickness no less than 0.3 μm and no more than 50 μm.

10. An electric double layer capacitor comprising a cathode, an anode, a separator to separate said cathode and anode, an electrolytic solution, and a container to house said cathode, anode, separator, and electrolytic solution, wherein said cathode is electrically connected to a cathode current collector, and said cathode current collector is comprised of an alloy of chromium and aluminum.

11. The electric double layer capacitor according to claim 10, wherein said chromium content in said alloy is no less than 10 atomic % and no more than 95 atomic %.

12. The electric double layer capacitor according to claim 10, wherein said cathode current collector is a film in a thickness no less than 0.3 μm and no more than 50 μm.

13. An electric double layer capacitor comprising a cathode, an anode, a separator to separate said cathode and anode, an electrolytic solution, and a container to house said cathode, anode, separator, and electrolytic solution, wherein said cathode is electrically connected to a cathode current collector, said cathode current collector is comprised of an alloy of chromium and aluminum, and said chromium content of said alloy is approximately 50 at %.
